(19) United States
(12) Patent Application Publication
(10) Pub. No.: US 2023/0361245 A1
(43) Pub. Date: Nov. 9, 2023

(54) SEMICONDUCTOR EPITAXY STRUCTURE, MANUFACTURING METHOD THEREOF, AND LED CHIP

(71) Applicant: XIAMEN CHANGELIGHT CO., LTD., Xiamen (CN)

(72) Inventors: Zhiwei LIN, Xiamen (CN); Kaixuan CHEN, Xiamen (CN); Jianjiu CAI, Xiamen (CN); Xiangjing ZHUO, Xiamen (CN); Gang YAO, Xiamen (CN); Wei CHENG, Xiamen (CN)

(73) Assignee: XIAMEN CHANGELIGHT CO., LTD., Xiamen (CN)

(21) Appl. No.: 18/219,035

(22) Filed: Jul. 6, 2023

Related U.S. Application Data
(63) Continuation of application No. PCT/CN2021/079038, filed on Mar. 4, 2021.
Application No. PCT/CN2021/079038 is a continuation of application No. PCT/CN2021/079039, filed on Mar. 4, 2021.

(30) Foreign Application Priority Data
Jan. 21, 2021 (CN) 202110079258.5
Feb. 7, 2021 (CN) 202110176774.X

(51) Int. Cl. H01L 33/12; H01L 33/06; H01L 33/32

(52) U.S. Cl. CPC H01L 33/12; H01L 33/06; H01L 33/32

(57) ABSTRACT

The present disclosure provides a semiconductor epitaxial structure, including a substrate, a first-type semiconductor layer, an active region comprising at least one quantum layer, and a second-type semiconductor layer sequentially stacked on a surface of the substrate; wherein the quantum layer comprises barrier layers and potential well layers, and the barrier layers are alternately stacked with the potential well layers, and wherein the quantum layer further comprises a growth temperature transition layer between a barrier layer and a potential well layer, or an electron confinement layer between a barrier layer and a potential well layer.

### CROSS-REFERENCE TO RELATED APPLICATION

This application claims priority to PCT Application No. PCT/CN2021/079038 filed on Mar. 4, 2021, which claims priority to Chinese Patent Application No. CN202110176774.X, filed on Feb. 7, 2021, and to PCT Application PCT/CN/2021/079039 filed on Mar. 4, 2021, which claims priority to Chinese Patent Application No. 202110079258.5, filed on Jan. 21, 2021, the entire disclosures of which are incorporated herein by reference for all purposes.

### TECHNICAL FIELD

The present disclosure relates to the field of light emitting diodes, in particular to a semiconductor epitaxial structure, a manufacturing method thereof, and an LED chip.

### BACKGROUND

Light Emitting Diode (referred to as: LED) is a semiconductor electronic component that can emit light. LED has the advantages of high efficiency, long life, small size, low power consumption, etc., and can be used in indoor and outdoor white light lighting, screen display, backlight and other fields. In the development of the LED industry, gallium nitride (GaN)-based materials are typical representatives of Group V-III compound semiconductors and improving the photoelectric performance of GaN-based LEDs has become the key to the semiconductor lighting industry.

Epitaxial wafers are the primary products in the LED manufacturing process. Existing GaN-based LED epitaxial wafers include a substrate, an N-type semiconductor layer, an active region and a P-type semiconductor layer. The substrate is used to provide a growth surface for epitaxial materials, the N-type semiconductor layer is used to provide electrons for composite light emission, the P-type semiconductor layer is used to provide holes for composite light emission, and the active region is used for radiation of electrons and holes Composite glow.

The active region includes a plurality of well layers and a plurality of barrier layers, the plurality of well layers and the plurality of barrier layers are alternately stacked, and the barrier layers confine the electrons and holes injected into the active region in the well layers for compound light emission. Generally, indium gallium nitride (InGaN) with a high indium composition is used as the material of the well layer, and gallium nitride (GaN) is used as the material of the barrier layer. Since the lattice constant of gallium nitride is 3.181 and that of indium nitride is 3.538, there is a large lattice mismatch between the well layer and the barrier layer, as well as between the well layer and the N-type semiconductor layer. The large lattice mismatch will cause the stress generated by the accumulation of lattice mismatch to seriously affect the recombination efficiency of electrons and holes in space, making the luminous efficiency of LEDs lower.

In addition, in the prior GaN-based semiconductor light-emitting epitaxial structure, the InGaN well layer is usually stacked on the GaN barrier layer during the growth process of the quantum well light-emitting layer. However, due to the lattice mismatch between InGaN and GaN, When the InGaN well layer is grown on the GaN barrier layer, dislocation defects will be generated in the InGaN well layer, so that the luminous efficiency of the entire quantum well light-emitting layer is reduced.

### SUMMARY

The present disclosure relates to the field of light emitting diodes, in particular to a semiconductor epitaxial structure, a manufacturing method thereof, and an LED chip, which solve the large lattice mismatch between the well layer and the barrier layer, and large lattice mismatch between the well layer and the first type semiconductor layer, and the compound efficiency problem caused by the stress due to lattice mismatch accumulation which will seriously affect the recombination efficiency of electrons and holes in space.

According to an aspect of the present disclosure, some embodiments provide a semiconductor epitaxial structure, comprising: a substrate, a first-type semiconductor layer, an active region comprising at least one quantum layer, and a second-type semiconductor layer sequentially stacked on a surface of the substrate; wherein the quantum layer comprises barrier layers and potential well layers, and the barrier layers are alternately stacked with the potential well layers, and wherein the quantum layer further comprises a growth temperature transition layer between a barrier layer and a potential well layer, or an electron confinement layer between a barrier layer and a potential well layer.

According to another aspect of the present disclosure, some embodiments provide a LED chip, comprising an epitaxial layer, an N-type electrode and a P-type electrode; wherein the epitaxial layer comprises a semiconductor epitaxial structure comprising: a substrate, a first-type semiconductor layer, an active region comprising at least one quantum layer, and a second-type semiconductor layer sequentially stacked on a surface of the substrate; wherein the quantum layer comprises barrier layers and potential well layers, and the barrier layers are alternately stacked with the potential well layers, and the quantum layer further comprises a growth temperature transition layer between a barrier layer and a potential well layer, and/or an electron confinement layer between a barrier layer and a potential well layer.

### BRIEF DESCRIPTION OF THE DRAWINGS

The accompanying drawings, which are incorporated in and constitute a part of this specification, illustrate examples consistent with the present disclosure and, together with the description, serve to explain the principles of the disclosure. The accompanying drawings in the following description are provided by some embodiments of the present disclosure, other drawings may be provided according to the provided drawings in some other embodiments.

FIG. 1 is a schematic structural diagram of a semiconductor epitaxial structure according to some embodiments of the present disclosure.

FIG. 2 is a schematic structural view of the active region of the semiconductor epitaxial structure according to some embodiments of the present disclosure.

FIG. 3 is a schematic diagram of the growth temperature relationship of each component layer in the active region according to some embodiments of the present disclosure.

FIG. 4 is a schematic diagram of the barrier height relationship of each constituent layer in the active region according to some embodiments of the present disclosure.

FIG. 5 is a schematic structural diagram of a semiconductor epitaxial structure according to some embodiments of the present disclosure.

FIG. 6 is a schematic diagram of the energy band relationship between the stress release layer and the quantum layer in the active region according to some embodiments of the present disclosure.

FIG. 7 is a schematic diagram of the relationship between the lattice constants of the stress release layer and the quantum layer in the active region according to some embodiments of the present disclosure.

FIG. 8 is a schematic diagram of the energy band relationship between the stress release layer and the quantum layer in the active region provided by another embodiment of the present disclosure.

FIG. 9 is a schematic diagram of the relationship between the lattice constants of the stress release layer and the quantum layer of the active region provided by another embodiment of the present disclosure.

### DETAILED DESCRIPTION

Embodiments of the present disclosure will be described in detail in the following descriptions, examples of which are shown in the accompanying drawings, in which the same or similar elements and elements having the same or similar functions are denoted by the same reference numerals throughout the descriptions. The embodiments described herein with reference to the accompanying drawings are explanatory and illustrative, which are used to generally understand the present disclosure. The embodiments shall not be construed to limit the present disclosure. Based on the embodiments of the present disclosure, all other embodiments obtained by persons of ordinary skill in the art without making creative efforts belong to the protection scope of the present disclosure.

Terms used in the present disclosure are merely for describing specific examples and are not intended to limit the present disclosure. The singular forms “one”, “the”, and “this” used in the present disclosure and the appended claims are also intended to include a multiple form, unless other meanings are clearly represented in the context. It should also be understood that the term “and/or” used in the present disclosure refers to any or all of possible combinations including one or more associated listed items.

Reference throughout the present disclosure to “one embodiment,” “an embodiment,” “an example,” “some embodiments,” “some examples,” or similar language means that a particular feature, structure, or characteristic described is included in at least one embodiment or example. Features, structures, elements, or characteristics described in connection with one or some embodiments are also applicable to other embodiments, unless expressly specified otherwise.

It should also be noted that in the present disclosure, relational terms such as first and second etc. are only used to distinguish one entity or operation from another entity or operation, and do not necessarily require or imply that these entities or operations any such actual relationship or order exists between. Moreover, the term “comprises”, “comprises” or any other variation thereof is intended to cover a non-exclusive inclusion such that an article or device comprising a set of elements includes not only those elements, but also other elements not expressly listed, or also include elements inherent in the article or device. Without further limitations, an element defined by the phrase “comprising a . . . ” does not exclude the presence of additional identical elements in an article or device comprising the aforementioned element.

Each embodiment in the present disclosure is described in a progressive manner, each embodiment focuses on the difference from other embodiments, and the same and similar parts of each embodiment can be referred to each other.

The description of the present disclosure is provided to enable any person skilled in the art to make or use the present application. Various modifications to these embodiments will be readily apparent to those skilled in the art, and the general principles defined herein may be implemented in other embodiments without departing from the spirit or scope of the present disclosure. Therefore, the present disclosure will not be limited to the embodiments shown herein but is to be accorded the widest scope consistent with the principles and novel features disclosed herein.

Some embodiments of the present disclosure provide a semiconductor epitaxial structure, including: a substrate, a first-type semiconductor layer, an active region comprising at least one quantum layer, and a second-type semiconductor layer sequentially stacked on a surface of the substrate; wherein the quantum layer comprises barrier layers and potential well layers, and the barrier layers are alternately stacked with the potential well layers, and wherein the quantum layer further comprises a growth temperature transition layer between a barrier layer and a potential well layer, or an electron confinement layer between a barrier layer and a potential well layer. The growth temperature transition layer is used for releasing the stress between the barrier layer and the potential well layer, and the electron confinement layer is used for strengthening electron restriction of the barrier layer and improve the barrier layer's internal quantum efficiency.

In some embodiments of the present disclosure, the growth temperature transition layer may be a cooling layer or a heating layer, and the electron confinement layer may be a deep well layer or a shallow well layer. In some embodiments, the semiconductor epitaxial structure may include multiple growth temperature transition layers ad multiple electron confinement layers.

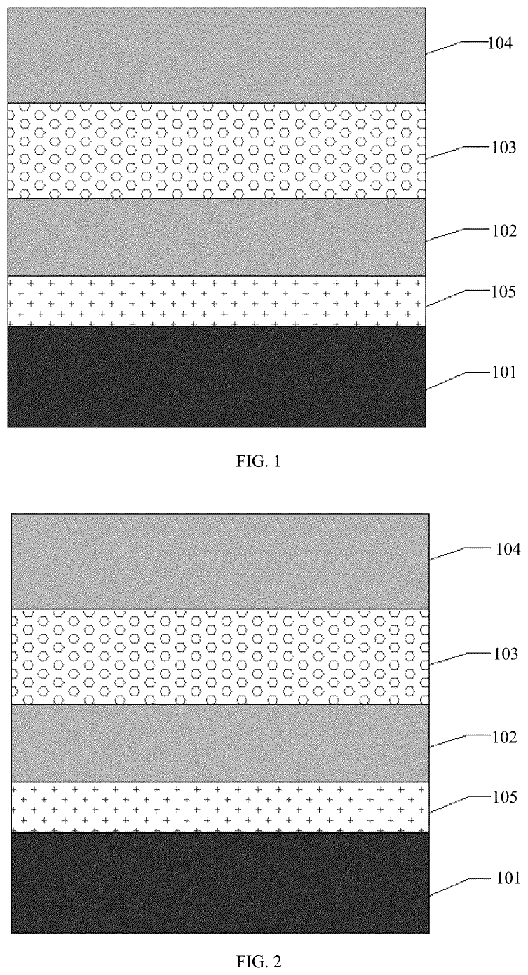

In some embodiments of the present disclosure, as shown in FIG. 1 and FIG. 2, a semiconductor epitaxial structure includes: substrate 101; a first-type semiconductor layer 102, an active region 103, and a second-type semiconductor layer 104 are sequentially stacked on the surface of the substrate 101.

The active region 103 includes alternately stacked barrier layers 36 and potential well layers 33, and a cooling layer 31 and a deep well layer 32 are sequentially provided on the side surface near the second-type semiconductor layer 104 of the at least one barrier layer 36, and a shallow well layer 34 and heating layer 35 are sequentially provided on the side surface near the first-type semiconductor layer 102 of the at least one barrier layer 36. Wherein, the cooling layer 31 and the heating layer 35 are used for the growth temperature transition between the barrier layer 36 and the potential well layer 33; the deep well layer 32 and the shallow well layer 34 are used for electron confinement to the barrier layer 36.

In some embodiments of the present disclosure, the type of the substrate 101 is not limited in the semiconductor epitaxial structure of this embodiment. For example, the substrate 101 may be but not limited to a sapphire substrate 101, a silicon substrate 101 and the like. In addition, the specific material types of the first-type semiconductor layer 102, the active region 33, and the second-type semiconductor layers 104 are not limited in the semiconductor epitaxial structure of this embodiment. For example, the first-type semiconductor layer 102 may be but not limited to a gallium nitride layer, and correspondingly, the second-type semiconductor layer 104 may be but not limited to a gallium nitride layer.

In some embodiments of the present disclosure, a buffer layer 105 may also be provided between the substrate 101 and the first-type semiconductor layer 102.

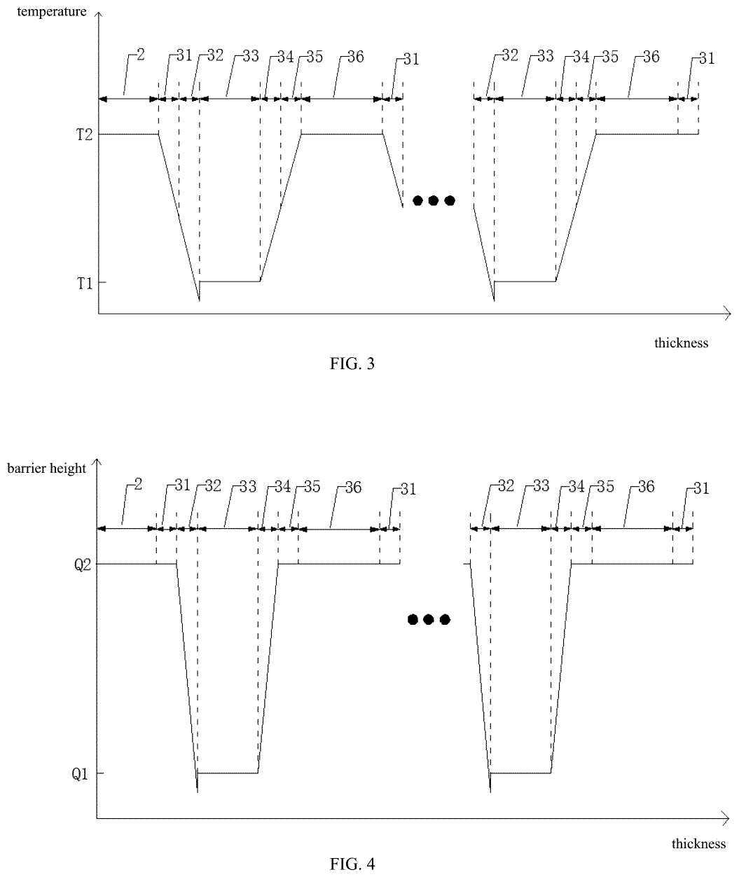

In some embodiments of the present disclosure, as shown in FIG. 3, during the growth process of the deep well layer 32, the deep well layer 32's growth temperature decreases from the growth temperature of the cooling layer 31 to the growth temperature T1 which is lower than the growth temperature of the potential well layer 33; during the growth process of the shallow well layer 34, the shallow well layer 34's growth temperature increases from the growth temperature T1 of the potential well layer 33 to the growth temperature of heating layer 35.

FIG. 3 shows a schematic diagram of the growth temperature relationship of each component layer in the active region 103 provided in the present embodiment. FIG. 3 illustrates the linear change of the growth temperature of each component layer in the active region 103. The present embodiment does not limit the specific temperatures and the change trends during the growth processes of the cooling layer 31, deep well layer 32, potential well layer 33, shallow trap layer 34, heating layer 35, and barrier layer 36. The change trends can be linear or nonlinear. At the same time, the present embodiment does not limit the temperature difference between the growth temperatures of the deep well layer 32 and the potential well layer 33, as long as the temperature difference transition is realized and the stress between the barrier layer 36 and the potential well layer 33 is effectively released.

In some embodiments of the present disclosure, as shown in FIG. 3, the growth temperature of the heating layer 35 is lower than the growth temperature T2 of the barrier layer 36. The temperature difference between the growth temperatures of the heating layer 35 and the barrier layer 36 is not limited to a specific value, as long as the growth temperature transition between the two can be realized while ensuring the growth quality.

In some embodiments of the present disclosure, each of the deep well 32 and the shallow well layer 34 includes an AlₓGa_{y}In_{z}N material layer with In component gradients, where 0≤x≤1, 0≤y≤1, 0≤z≤1. In some embodiments, the deep well 32 or the shallow well layer 34 may be an AlGaInN material layer or a GaInN material layer.

In some embodiments of the present disclosure, as shown in FIG. 4, the deep well layer 32 and the shallow well layer 34 include material layers with gradually changing bandgaps, and the bandgap of the shallow well layer 34 is always greater than the bandgap of the potential well layer 33, and the bandgap of a region of the deep well layer 32 is smaller than the bandgap of the potential well layer 33.

FIG. 4 shows a schematic diagram of the barrier height relationship of each component layer in the active region 103 according some embodiments of the present disclosure. The contents of FIG. 4 exemplify the linear change of the band relationship of each component layer in the active region 103, and does not limit the specific band values and their change trends during the growth processes of the cooling layer 31, deep well layer 32, potential well layer 33, shallow trap layer 34, heating layer 35 and barrier layer 36. The change trends can be linear or nonlinear.

In some embodiments of the present disclosure, each of the heating layer 35 and the cooling layer 31 includes non-doped material layers, each of the deep well layer 32 and the shallow well layer 34 includes P-type doped material layers, and the doping concentration is not higher than 5*10¹⁷ cm⁻³.

In some embodiments of the present disclosure, each of the heating layer 35 and the cooling layer 31 includes AlₐGa_{b}N material layers, where 0≤a≤1, 0≤b≤1. In some embodiments, the heating layer 35 or the cooling layer 31 may be a AlGaN layer or a GaN layer.

In some embodiments of the present disclosure, the thickness of the potential well layer 33 is three times or more than the thickness of the deep well layer 32 or the shallow well layer 34.

In some embodiments of the present disclosure, the thicknesses of both the deep well layer 32 and the shallow well layer 34 are 0˜10 nm.

In some embodiments of the present disclosure, the thickness of the barrier layer 36 is 4 times or more than the thickness of the heating layer 35 or the cooling layer 31.

In some embodiments of the present disclosure, the thicknesses of both the heating layer 35 and the cooling layer 31 are 0˜20 nm.

In some embodiments of the present disclosure, the barrier layer 36 is doped with n-type impurities.

Some embodiments of the present disclosure also provide a method for manufacturing a semiconductor epitaxial structure, and the method includes the following steps:

Step S01, providing a substrate 101.

Step S02, sequentially growing a buffer layer 105, a first-type semiconductor layer 102, an active region 103, and a second-type semiconductor layer 104 on the surface of the substrate 101.

The active region 103 includes alternately stacked barrier layers 36 and potential well layers 33, a cooling layer 31 and a deep well layer 32 are sequentially provided on the side surface near the second-type semiconductor layer 104 of the at least one barrier layer 36, and a shallow well layer 34 and a heating layer 35 are sequentially provided on the side surface near the first-type semiconductor layer 102 of the at least one barrier layer 36. Wherein, the cooling layer 31 and the heating layer 35 are used for the growth temperature transition between for the barrier layer 36 and the potential well layer 33; the deep well layer 32 and the shallow well layer 34 are used for electron confinement to the barrier layer 36.

In some embodiments of the present disclosure, each of the deep well 32 and the shallow well layer 34 includes an AlₓGa_{y}In_{z}N material layer with In component gradients, where 0≤x≤1, 0≤y≤1, 0≤z≤1. In some embodiments, the deep well 32 or the shallow well layer 3 may be an AlGaInN layer or a GaInN layer.

In some embodiments of the present disclosure, each of the heating layer 35 and the cooling layer 31 includes an AlₐGa_{b}N material layer, wherein, 0≤a≤1, 0≤b≤1. In some embodiments, the heating layer 35 or the cooling layer 31 may be an AlGaN material layer or a GaN material layer;

In some embodiments of the present disclosure, during the growth process of the deep well layer 32, the deep well layer 32's growth temperature decreases from the growth temperature of the cooling layer 31 to lower than the growth temperature of the potential well layer 33; during the growth process of the shallow well layer 34, the shallow well layer 34's growth temperature increases from the growth temperature of the potential well layer 33 to the growth temperature of heating layer 35.

In some embodiments of the present disclosure, the growth temperature of the heating layer 35 is lower than the growth temperature of the barrier layer 36.

Some embodiments of the present disclosure also provide an LED chip, including an epitaxial layer, an N-type electrode and a P-type electrode, and the epitaxial layer includes any one of the semiconductor epitaxial structures described above.

Through the above technical solutions, it can be known that the semiconductor epitaxial structure provided by the present embodiment is provided with a cooling layer 31 and a deep well layer 32 on at least one side surface of the barrier layer 36 close to the second type semiconductor layer 102 in sequence, and a shallow trap layer 34 and a heating layer 35 are provided on at least one side surface of the barrier layer 36 close to the first type semiconductor layer 4 in sequence; wherein, the cooling layer 31 and the heating layer 35 are used for the growth temperature transition between the barrier layer 36 and the potential well layer 33; the deep well layer 32 and the shallow well layer 34 are used for electron restriction of the barrier layer 36; further, in the growth process of the deep well layer 32, its growth temperature is reduced from the growth temperature of the cooling layer 31 to below the growth temperature of the potential well layer 33; in the growth process of the shallow well layer 34, its growth temperature is increased from the growth temperature of the potential well layer 33 to the growth temperature of the heating layer 35. By controlling the growth temperature, stress between the barrier layer 36 and the potential well layer 33 can be effectively released; meanwhile, a trap-like structure is further formed at both ends before and after the potential well layer 33, which is beneficial to strengthen electron restriction of the barrier layer 36 and improve its internal quantum efficiency.

Secondly, each of the heating layer 35 and the cooling layer 31 includes non-doped material layers, each of the deep well layer 32 and the shallow well layer 34 respectively includes P-type doped material layers, and the doping concentration is not higher than 5*10¹⁷ cm⁻³, Therefore, on the one hand, the active region 103 grows the formed V-pits structure combined with the micro-doped P-type impurities in the deep well layer 32 and the shallow well layer 34 can effectively deal with different crystal interface energies, and effectively release the mutual stress caused by the potential well layer 33 and barrier layer 36 during the growth process of the deep well layer 32 and shallow well layer 34; on the other hand, the number of holes in the active region 103 can be effectively increased and the formation of a built-in electric field in the active region 103 can be avoided, thereby effectively improving the internal quantum efficiency of the active region 103.

Furthermore, the thickness of the potential well layer 33 is 3 times or more than the thickness of the deep well layer 32 or the shallow well layer 34, and the thickness of the barrier layer 36 is 4 times or more than the thickness of the heating layer 35 or the cooling layer 31, while avoiding the overall poor crystal quality of the active region 103 due to the too small thickness of the barrier layer 36, effectively releasing the stress between the potential well 33 layer and the barrier layer 36 during the growth process of the deep well layer 32 and the shallow well layer 34, and increase the number of holes in the active region 103.

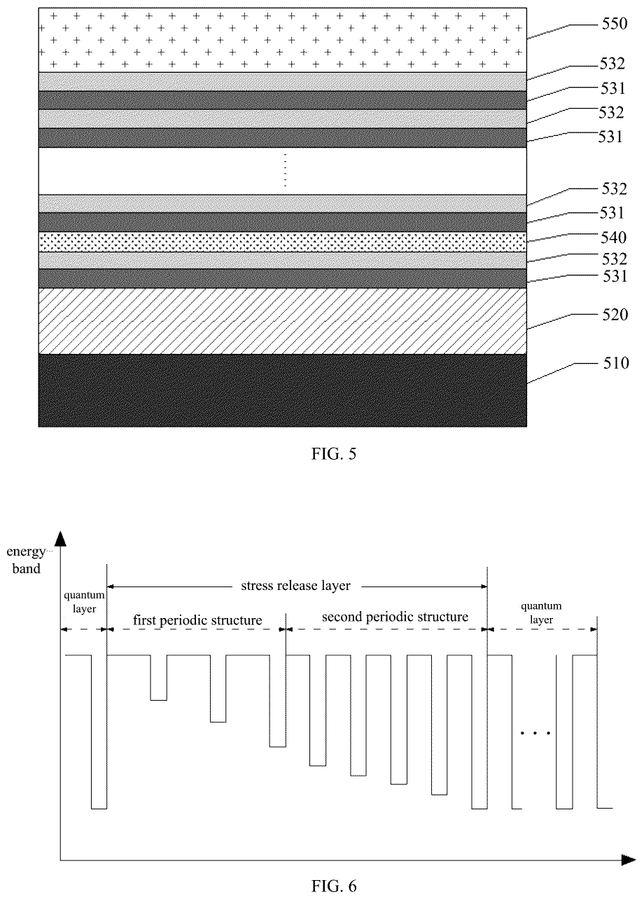

In some embodiments of the present disclosure, as shown in FIG. 5, a semiconductor epitaxial structure includes: the substrate 510, and the first-type semiconductor layer 520, the active region 530, and the second-type semiconductor layer 550 sequentially stacked on the surface of the substrate 510.

The active region 530 includes n quantum layers stacked along a first direction, each quantum layer includes a barrier layer 531 and a well layer 532 and at least one stress release layer 540 is provided between two adjacent quantum layers; where n is a positive integer; the first direction is perpendicular to the substrate 510 and points from the substrate 510 to the first-type semiconductor layer 520.

In some embodiments of the present disclosure, the type of substrate 510 is not limited in the semiconductor epitaxial structure of this embodiment. For example, the substrate 510 can be a sapphire substrate, a silicon substrate, and so on. In addition, the specific material types of the first-type semiconductor layer 520, the active region 530 and the second-type semiconductor layer 550 are not limited in the semiconductor epitaxial structure of this embodiment. For example, the first-type semiconductor layer 520 can be gallium nitride layer, and correspondingly, the second-type semiconductor layer 550 can be gallium nitride layer.

In some embodiments of the present disclosure, the bandgap of the stress release layer 540 is not less than that of the active region 530, and the lattice constant of the stress release layer 540 is not greater than that of the active region 530.

In some embodiments of the present disclosure, the stress release layer 540 includes several sub-stress release layers 540 stacked along a first direction in turn, and each sub-stress release layer 540 includes a periodic structure.

In some embodiments of the present disclosure, the lattice constants of the sub-stress release layers 540 of different periodic structures increase along the first direction, and the lattice constants of each of the sub-stress release layers 540 are not greater than the lattice constant of the active region 530. The energy bands of the sub-stress release layers 540 of different periodic structures decrease along the first direction, and the energy bands of each of the sub-stress release layers 540 are not smaller than the energy band of the active region 530.

In some embodiments of the present disclosure, the energy bands of the sub-stress release layers 540 in the same periodic structure are the same or decrease along the first direction.

In some embodiments of the present disclosure, the lattice constants of the sub-stress release layers 540 in the same periodic structure are the same or increase along the first direction.

In some embodiments of the present disclosure, each of the sub-stress release layers 540 is composed of alternate cycles of high and low energy band material layers.

In some embodiments of the present disclosure, the lattice constant of each of the low-energy band material layers along the first direction gradually increases; the energy band of each of the low-energy band material layers along the first direction gradually decreases.

In some embodiments of the present disclosure, each of the sub-stress release layers 540 includes AlₓGa_{y}In_{1-x-y}N, and the high and low energy band material layers and their corresponding lattice constant and energy band relationship are obtained by adjusting the composition of Al and or Ga; wherein, 0≤x<1, 0<y≤1.

In some embodiments of the present disclosure, the stress release layer 540 is disposed at a junction between the first quantum layer and the second quantum layer adjacent to the first quantum layer in the active region 530 along the first direction.

In this embodiment of the present disclosure, the stress release layer 540 includes 3 sub-stress release layers 540 having the first period structures and 5 sub-stress release layers 540 having the second period structures.

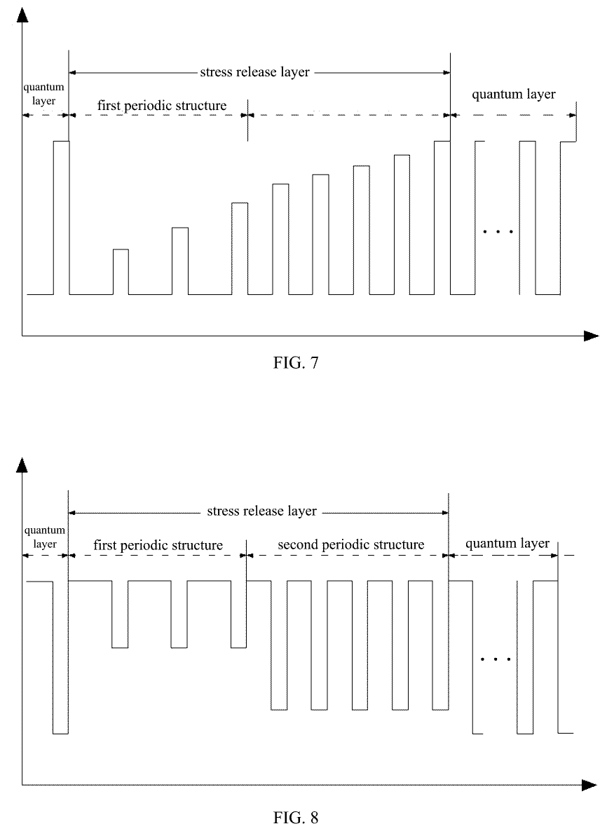

FIG. 6 is a schematic diagram of the energy band relationship between the stress release layer and the quantum layer in the active region provided by the embodiment of the present disclosure, which exemplifies that when the stress release layer is presented in two periodic structures, the band of each sub-stress release layer in the same periodic structure decreases along the first direction. The contents of FIG. 6 are not intended to limit the scope of the present disclosure.

FIG. 7 is a schematic diagram of the lattice constant relationship between the stress release layer and the quantum layer in the active region provided by the embodiment of the present disclosure, which exemplifies that when the stress release layer is presented in two periodic structures, the lattice constant of each sub-stress release layer in the same periodic structure increases along the first direction. The contents of FIG. 7 are not intended to limit the scope of the present disclosure.

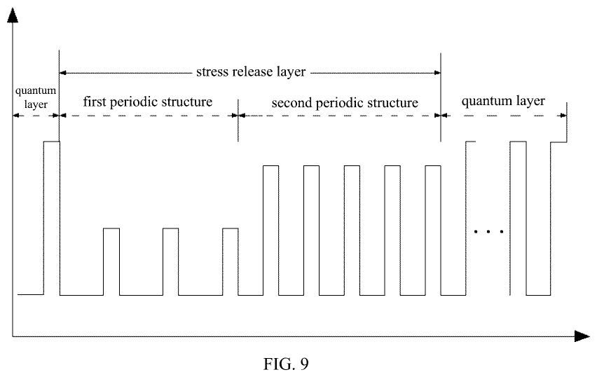

FIG. 8 is a schematic diagram of the energy band relationship between the stress release layer and the quantum layer in the active region provided by other embodiments of the present disclosure. which exemplifies that when the stress release layer is presented in two periodic structures, the band of each sub-stress release layer in the same periodic structure is the same. The contents of FIG. 8 are not intended to limit the scope of the present disclosure.

FIG. 9 is a schematic diagram of the lattice constant relationship between the stress release layer and the quantum layer in the active region provided by other embodiments of the present disclosure. which exemplifies that when the stress release layer is presented in two periodic structures, the lattice constants of each of the sub-stress release layers are the same. The contents of FIG. 9 are not intended to limit the scope of the present.

FIG. 6 to FIG. 9 illustrate that the energy bands of the high-energy band material layers of the barrier layer 531 and the stress release layer 540 in the active region 530 are equal. In other embodiments, the energy bands of each high-energy band material layer of the stress release layer 540 may be gradually changed, which is not specifically limited in the present disclosure.

In some embodiments of the present disclosure, as shown in FIG. 6 and FIG. 8, the energy bands of the low-energy material layers in the first period are the same or decrease along the first direction, and the energy bands of the low-energy material layers in the second period are the same or decrease along the first direction, and the energy band of any low-energy material layer in the first period is greater than the energy band of any low-energy material layer in the second period.

Embodiments of the present disclosure also provides a method for manufacturing a semiconductor epitaxial structure, and the method includes the following steps:

Step S01, providing a substrate 510.

Step S02, sequentially growing a first-type semiconductor layer 520, an active region 530, and a second-type semiconductor layer 550 on the surface of the substrate 510.

The active region 530 includes n quantum layers stacked in sequence along the first direction, each of the quantum layers includes a barrier layer 531 and a potential well layer 532, and at least a stress release layer 540 is provided between two adjacent quantum layers; Wherein, n is a positive integer; the first direction is perpendicular to the substrate 510 and is directed from the substrate to the first-type semiconductor layer 520.

The stress release layer is formed by a temperature-variable growth method, the stress release layer 540 includes several sub-stress release layers 540 stacked in sequence along the first direction, and each of the sub-stress release layers includes a periodic structure.

Wherein, the lattice constants of the sub-stress release layers 540 of different periodic structures increase along the first direction; the energy bands of the sub-stress release layers 540 of different periodic structures decrease along the first direction, and each of the sub-stress release layers 540 energy bands are higher than the energy band of the active region 530.

The energy bands of the sub-stress release layers 540 in the same periodic structure are the same or decrease along the first direction.

Preferably, each of the sub-stress release layers 540 is composed of alternating cycles of high and low energy band material layers; the lattice constant of each of the low energy band material layers along the first direction gradually increases; the energy bands of each of the low-energy band material along the first direction layers gradually decrease.

Wherein, each of the sub-stress release layers 540 includes AlₓGa_{y}In_{1-x-y}N, and the high and low energy band material layers and their corresponding lattice constant and energy band relationship are obtained by adjusting the composition of Al and or Ga; wherein, 0≤x<1, 0<y≤1.

Embodiments of the present disclosure also provide an LED chip, including: the semiconductor epitaxial structure described in any one of the above, the N-type electrode, forming an ohmic contact with the N-type semiconductor layer, and the P-type electrode, forming an ohmic contact with the P-type semiconductor layer.

The semiconductor epitaxial structure provided by the present disclosure includes a first-type semiconductor layer 520, an active region 530, and a second-type semiconductor layer 550 stacked in sequence on the surface of the substrate 510. The active region 530 includes quantum layers stacked sequentially in the first direction, each of the quantum layers includes a barrier layer 531 and a potential well layer 532, and at least a stress release layer 540 is provided between two adjacent quantum layers to solve the problem of lattice mismatch between the potential well layer 532 and the barrier layer 531, and between the potential well layer 532 and the first-type semiconductor layer 520. In this way, the influence of the stress generated by the accumulated lattice mismatch on the recombination efficiency of electrons and holes in space is avoided.

Secondly, the energy band of the stress release layer 540 is higher than the energy band of the active region 530, and the lattice constant of the stress release layer 540 is lower than that of the active region 530. Wherein, the stress release layer 540 includes several sub-stress release layers 540 stacked in sequence along the first direction, and each of the sub-stress release layers 540 includes a periodic structure. Preferably, the lattice constants of the sub-stress release layers 540 of different periodic structures increase along the first direction; the energy bands of the sub-stress release layers 540 of different periodic structures decrease along the first direction, and each of the energy bands of the sub-stress release layers 540 of are higher than the energy bands of the active region 530; the energy bands of the sub-stress release layers 540 in the same periodic structure are the same or decrease along the first direction. Further make the lattice matching between the potential well layer 532 and the barrier layer 531 and the first-type semiconductor layer 520 more sufficient, thereby effectively improving the recombination efficiency of electrons and holes in the active region in space and suppressing the high-quality first-type semiconductor layer 520 where dislocations occur.

Then, by disposing the stress release layer 540 at the junction between the first quantum layer and the second quantum layer adjacent to the first quantum layer in the active region 530 along the first direction, while ensuring the lattice matching of the stress release layer 540 having beneficial effects, the dislocation between the active region 520 and the first-type semiconductor layer 520 can be more effectively suppressed.

The manufacturing method of the semiconductor epitaxial structure provided by the present disclosure not only realizes the above-mentioned beneficial effects of the semiconductor epitaxial structure, but also has a simple and convenient manufacturing process and is convenient for production.

The LED chip provided by the present disclosure is obtained on the basis of the above-mentioned semiconductor epitaxial structure, so it has the beneficial effects of the above-mentioned semiconductor epitaxial structure, and at the same time, its process is simple and convenient for production.

What is claimed is:

1. A semiconductor epitaxial structure, comprising:
a substrate, a first-type semiconductor layer, an active region comprising at least one quantum layer, and a second-type semiconductor layer sequentially stacked on a surface of the substrate;
wherein the quantum layer comprises barrier layers and potential well layers, and the barrier layers are alternately stacked with the potential well layers, and
wherein the quantum layer further comprises a growth temperature transition layer between a barrier layer and a potential well layer, or an electron confinement layer between a barrier layer and a potential well layer.

2. The semiconductor epitaxial structure according to claim 1, wherein the growth temperature transition layer comprises a cooling layer or a heating layer; and,
the electron confinement layer comprises a deep well layer or a shallow well layer.

3. The semiconductor epitaxial structure according to claim 2, wherein at least one barrier layer comprises a first surface close to the first-type semiconductor layer, and a second surface close to the second-type semiconductor layer,
a cooling layer and a deep well layer are sequentially stacked on the second surface,
and a shallow well layer and a heating layer are sequentially stacked on the first surface.

4. The semiconductor epitaxial structure according to claim 3, wherein a growth temperature of the deep well layer is lowered from a growth temperature of the cooling layer to a temperature lower than a growth temperature of a potential well layer, or,
a growth temperature of a shallow well layer is increased from a growth temperature of a potential well layer to a growth temperature of a heating layer.

5. The semiconductor epitaxial structure according to claim 3, wherein a growth temperature of a heating layer is lower than a growth temperature of the at least one barrier layer.

6. The semiconductor epitaxial structure according to claim 3, wherein either of the deep well layer and the shallow well layer comprises an AlₓGa_{y}In_{z}N layer with a gradually changing composition of In, wherein each of x, y, and z is no less than 0 and no greater than 1.

7. The semiconductor epitaxial structure according to claim 3, wherein either of the deep well layer and the shallow well layer comprises a material layer with a gradually changing bandgap, a bandgap range of the shallow well layer is greater than a bandgap of a potential well layer, and a bandgap of a region of the deep well layer is smaller than the bandgap of the potential well layer.

8. The semiconductor epitaxial structure according to claim 3, wherein either of the heating layer and the cooling layer comprises a non-doped material layer, and either of the deep well layer and the shallow well layer comprises a P-type doped material layer with a doping concentration being not higher than 5*10¹⁷ cm⁻³.

9. The semiconductor epitaxial structure according to claim 3, wherein either the heating layer or the cooling layer comprises an AlₐGa_{b}N layer, wherein each of a and b is no less than 0 and no greater than 1; or
a thickness of the potential well layer is 3 times or more than a thickness of the deep well layer or the shallow well layer; or
both the deep well layer and the shallow well layer have a thickness of 0˜10 nm; or
a thickness of the at least one barrier layer is 4 times or more than a thickness of the heating layer or cooling layer; or
thicknesses of both the heating layer and the cooling layer are 0˜20 nm.

10. The semiconductor epitaxial structure according to claim 1, wherein the active region comprises multiple quantum layers stacked in sequence along a first direction, and a stress release layer between two adjacent quantum layers;
wherein the first direction is perpendicular to the substrate and is directed from the substrate to the first-type semiconductor layer.

11. The semiconductor epitaxial structure according to claim 10, wherein an energy band of the stress release layer is not smaller than an energy band of the active region, and a lattice constant of the stress release layer is not greater than a lattice constant of the active region.

12. The semiconductor epitaxial structure according to claim 10, wherein the stress release layer comprises multiple sub-stress release layers stacked in sequence along the first direction, and each of the sub-stress release layers comprises a periodic structure.

13. The semiconductor epitaxial structure according to claim 12, wherein lattice constants of the sub-stress release layers having different periodic structures increase along the first direction, a lattice constant of each of the sub-stress release layers is not greater than a lattice constant of the active region, and
energy bands of the sub-stress release layers having the different periodic structures decrease along the first direction, and an energy band of each of the sub-stress release layers is not smaller than an energy band of the active region.

14. The semiconductor epitaxial structure according to claim 12, wherein sub-stress release layers in a same periodic structure have a same energy band, or have energy bands decreasing along the first direction.

15. The semiconductor epitaxial structure according to claim 12, wherein each of the sub-stress release layers comprises alternate cycle structures, each of the alternate cycle structures comprising a high energy band material layer and a low energy band material layer.

16. The semiconductor epitaxial structure according to claim 15, wherein lattice constants of low-energy band material layers gradually increases along the first direction, and energy bands of low-energy band material layers gradually decreases along the first direction; or
each of the sub-stress release layers comprises AlₓGa_{y}In_{1-x-y}N, where 0≤x<1, 0<y≤1, and either the high energy band material layer or the low energy band material layer has a lattice constant and an energy band relationship, both of which determined by a composition of Al or a composition of Ga.

17. The semiconductor epitaxial structure according to claim 14, wherein the active region comprises a first stress release layer between a first quantum layer prepared on the first-type semiconductor layer and a second quantum layer prepared adjacent to the first quantum layer.

18. The semiconductor epitaxial structure according to claim 17, wherein the first stress release layer comprises 3 first sub-stress release layers having first period structures and 5 second sub-stress release layers having second period structures.

19. The semiconductor epitaxial structure according to claim 18, wherein each low-energy band material layer in the first period structures has a same energy band, or an energy band decreasing along the first direction, and
each low-energy band material layer in the second period structures has a same energy band, or an energy band decreasing along the first direction, and
an energy band of any low-energy-band material layer in the first period structures is greater than an energy band of any low-energy-band material layer in the second period structures.

20. A LED chip, comprising an epitaxial layer, an N-type electrode, and a P-type electrode;
wherein the epitaxial layer comprises a semiconductor epitaxial structure comprising:
a substrate, a first-type semiconductor layer, an active region comprising at least one quantum layer, and a second-type semiconductor layer sequentially stacked on a surface of the substrate;
wherein the quantum layer comprises barrier layers and potential well layers, and the barrier layers are alternately stacked with the potential well layers, and
the quantum layer further comprises a growth temperature transition layer between a barrier layer and a potential well layer, and/or an electron confinement layer between a barrier layer and a potential well layer.
